(19) United States
(12) Patent Application Publication
(10) Pub. No.: US 2019/0386645 A1
(43) Pub. Date: Dec. 19, 2019

(54) SWITCHING CIRCUIT WITH IMPROVED LINEARITY

(71) Applicant: Realtek Semiconductor Corp., HsinChu (TW)

(72) Inventors: Chia-Chi Tsai, Hsinchu County (TW); Li-Lung Kao, New Taipei City (TW)

(21) Appl. No.: 16/443,822

(22) Filed: Jun. 17, 2019

(30) Foreign Application Priority Data
Jun. 19, 2018 (TW) 107120911

(51) Int. Cl. H03K 3/0233; H03K 19/0185

(52) U.S. Cl. CPC H03K 3/0233; H03K 19/018507

(57) ABSTRACT

A circuit including a switch and a level shift circuit is provided. The switch includes a control terminal and an input terminal. The input terminal is arranged to receive an input voltage, and the control terminal is arranged to receive a control voltage that controls a state of the switch. The level shift circuit includes a level-shifting input terminal and a level-shifting output terminal. The level-shifting input terminal is coupled to the input terminal for receiving the input voltage, and the level shift circuit is arranged to shift the input voltage to generate a shifted voltage on the level-shifting output terminal, and the control voltage is generated based on the shifted voltage.

### BACKGROUND OF THE INVENTION

### 1. Field of the Invention

The present invention relates to a switching circuit, and more particularly, to a circuit having high linearity, operable under negative voltage, and applicable to high power output audio product.

### 2. Description of the Prior Art

Analog switches are commonly implemented with transmission gates, utilizing a parallel connection of P-type and N-type Metal Oxide Semiconductor Field Effect Transistors (MOSFETs) for reducing the equivalent impedance and improving linearity. However, unless a steep cost due to a large circuit area is incurred, such design may hardly meet specifications required by audio products. In addition, since the source and the base of a MOSFET are connected to each other, once an input voltage is a negative voltage, leakage current will occur due to an electrical connection between the base of the P-type MOSFET and the P-substrate being established. Hence, transmission gate-based switching circuits may be unsuitable in this regards for products such as the ground reference headphone amplifier (HP_AMP). However, this design is commonly used for cost saving of components.

### SUMMARY OF THE INVENTION

An objective of the present invention is to provide a circuit that has high linearity.

An embodiment of the present invention provides a circuit that includes a switch and a level-shifting circuit. The switch includes a control terminal and an input terminal. The input terminal is arranged to receive an input voltage, and the control terminal is arranged to receive a control voltage that controls a state of the switch. The level-shifting circuit includes a level-shifting input terminal and a level-shifting output terminal, and the level-shifting input terminal is coupled to the input terminal for receiving the input voltage. The level-shifting circuit is arranged to shift the input voltage for generating a shifted voltage at the level-shifting output terminal, and the control voltage is generated based on the shifted voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a switching circuit according to an embodiment of the present invention.

FIG. 2 is a diagram illustrating a level-shifting circuit according to an embodiment of the present invention.

FIG. 3 is a diagram illustrating a level-shifting circuit according to another embodiment of the present invention.

### DETAILED DESCRIPTION

Some phrases in the present specification and claims refer to specific elements; however, please note that the manufacturer might use different terms to refer to the same elements. Further, in the present specification and claims, the term “comprising” is open type and should not be viewed as the term “consists of.” The term “electrically coupled” can refer to either direct connection or indirect connection between elements. Thus, if the specification describes that a first device is electrically coupled to a second device, the first device can be directly connected to the second device, or indirectly connected to the second device through other devices or means.

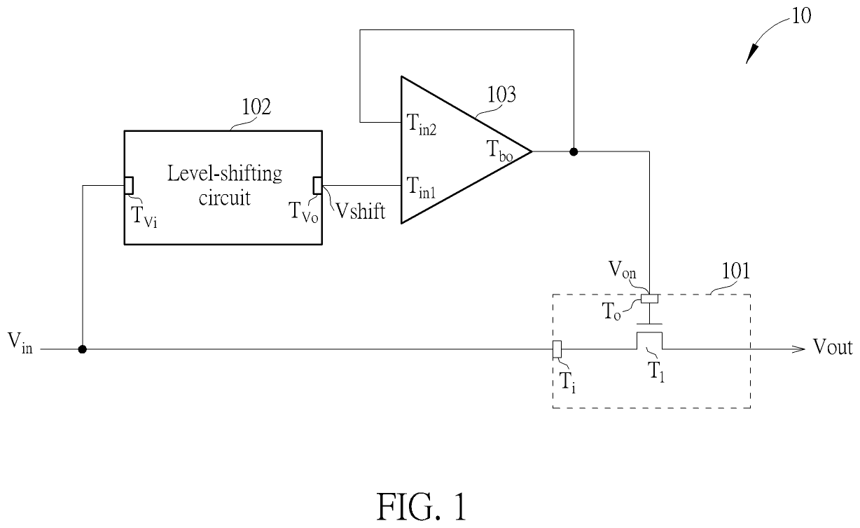

FIG. 1 is a diagram illustrating a switching circuit 10 according to an embodiment of the present invention. As shown in FIG. 1, the switching circuit 10 is arranged to receive an input voltage Vᵢₙ and arranged to output an output voltage Vₒᵤₜ. The switching circuit 10 comprises a switch 101, a level-shifting circuit 102 and a buffering circuit 103, wherein the switch 101 comprises a control terminal Tₒ and an input terminal Tᵢ; and the level-shifting circuit 102 comprises a level-shifting input terminal Tᵥᵢ and a level-shifting output terminal T_{vc}. The input terminal Tᵢ of the switch 101 receives the input voltage Vᵢₙ, and a control voltage Vₒₙ at the control terminal Tₒ determines the on or off state of the switch 101. The level-shifting input terminal Tᵥᵢ of the level-shifting circuit 102 receives the input voltage Vᵢₙ to make the level-shifting circuit 102 shift the input voltage Vᵢₙ for generating a shifted voltage V_{shift} at the level-shifting output terminal Tᵥₒ. In this embodiment, the buffering circuit 103 is implemented with an amplifier circuit, wherein the buffering circuit 103 comprises a first input terminal Tᵢₙ₁, a second input terminal Tᵢₙ₂ and an output terminal T_{bc}, wherein the first input terminal Tᵢₙ₁ is coupled to the level-shifting output terminal Tᵥₒ in order to receive the shifted voltage V_{shift}. As shown in the figure, the second input terminal Tᵢₙ₂ is coupled to the output terminal T_{bo}, making the amplifier circuit form a negative feedback in order to serve as a buffering circuit. The buffered shifted voltage V_{shift} is outputted to the control terminal Tₒ, thereby forming the control voltage Vₒₙ in order to control the on or off state of the switch 101. One thing should be noted is that the objective of configuring the buffering circuit 103 is to avoid signal distortions when the output voltage Vₒᵤₜ is coupled to a heavy load, but the buffering circuit 103 is a removable circuit, and can be omitted in some other embodiments. In this way, the level-shifting output terminal Tᵥₒ will be connected to the control terminal Tₒ in order to make the shifted voltage V_{shift} equal to the control voltage Vₒₙ and thereby control the on or off state of the switch 101. In this embodiment, the switch 101 comprises a transistor T₁. More specifically, the transistor T₁ may be a Metal Oxide Semiconductor Field Effect Transistor (MOSFET), wherein the gate of the transistor T₁ is coupled to the control terminal Tₒ, the source thereof is coupled to the input terminal Tᵢ in order to receive the input voltage Vᵢₙ, and the output voltage Vₒᵤₜ is generated at the drain thereof. One thing should be noted is that the present invention does not limit the type of the transistor T₁, e.g. the transistor T₁ may be a P-type MOSFET or N-type MOSFET. For example, when the transistor T₁ is an N-type MOSFET, the level-shifting circuit 102 will shift the input voltage Vᵢₙ up to a higher voltage value, making the control voltage of the gate of the transistor T₁ higher than that of the source. In another example, when the transistor T₁ is a P-type MOSFET, the level-shifting circuit 102 will shift the input voltage Vᵢₙ down to a lower voltage level, making the control voltage at the gate of the transistor T₁ lower than that at the source. Since one skilled in the art should be readily to realize how to perform the operation of controlling the level difference between the gate and source of a transistor to make the level difference larger than the threshold voltage of the transistor in order to turn on the transistor, the detailed descriptions are omitted here for brevity.

More specifically, after providing the input voltage Vᵢₙ to the level-shifting circuit 102 through the level-shifting input terminal Tᵥᵢ, generating the shifted voltage V_{shift} via a level-shifting operation, and generating the control voltage Vₒₙ at the gate of the transistor T₁ via the buffering circuit 103, the level difference between the gate and the source is ensured to exceed the threshold voltage of the transistor T₁. Hence, the control voltage of the switch 101 is protected against the influence of the negative voltage of the input voltage Vᵢₙ and can be turned on anytime, and thus the linearity can be optimized. Compared with traditional transmission gate switches, the switching circuit 10 of the present invention benefits from the increase of linearity. Thus, even when the output is connected to a heavy load, configuring relatively large turn-on impedance will not easily cause distortions, and thus the circuit area and manufacturing cost can be reduced.

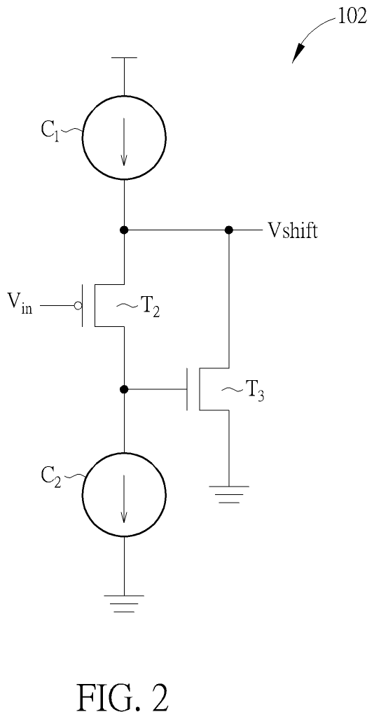

FIG. 2 is a diagram illustrating a level-shifting circuit 102 according to an embodiment of the present invention. The level-shifting circuit 102 comprises the transistors T₂, T₃ and the current sources C₁, C₂. In this embodiment, the transistor T₂ is implemented with a P-type MOSFET and the transistor T₃ is implemented with an N-type MOSFET, but the present invention is not limited thereto. One skilled in the art is readily to realize that the transistors T₂ and T₃ can be implemented by different types of elements. As shown in FIG. 2, the gate of the transistor T₂ is coupled to the input voltage Vᵢₙ for generating the shifted voltage V_{shift} at the source of the transistor T₂. The drain of the transistor T₂ is coupled to the gate of the transistor T₃, the drain of the transistor T₃ is coupled to the source of the transistor T₂, the source of the transistor T₃ is coupled to a reference voltage (depicted as the ground voltage in this embodiment), the current source C₂ is coupled between the drain of the transistor T₂ and the ground voltage, and the current source C₁ is coupled between the source of the transistor T₂ and a reference voltage (a power supply voltage in this embodiment). In this embodiment, the level-shifting circuit 102 may be implemented with a source follower circuit, but the present invention is not limited thereto. In some other embodiments, the level-shifting circuit 102 may be implemented with other circuits. Any method of generating shifted voltage V_{shift} by shifting the input voltage Vᵢₙ a level difference shall fall within the scope of the present invention.

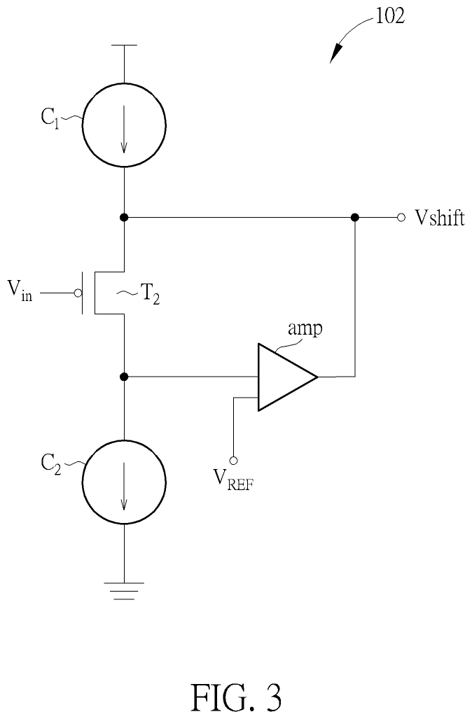

FIG. 3 is a diagram illustrating the level-shifting circuit 102 according to another embodiment of the present invention. The difference between the embodiment shown in FIG. 3 and the embodiment shown in FIG. 2 is that the transistor T₃ of the embodiment of FIG. 2 is replaced with an amplifier amp in the embodiment of FIG. 3, while other elements remain unchanged. An input terminal of the amplifier amp is coupled to the drain of the transistor T₂, an input terminal thereof is coupled to a reference voltage Vref, and an output terminal thereof is coupled to the source of the transistor T₂. In this way, the output impedance of the current source C₂ can be increased, thereby optimizing the performance of the level-shifting circuit.

To briefly summarize, the present invention proposes a switching circuit which generates a shifted voltage by using a level-shifting circuit to shift the input voltage shift for a level difference. Further, a buffering circuit can be utilized to generate the shifted voltage at a gate of a MOSFET, causing a level difference between the gate and source, which is larger than the threshold voltage of the MOSFET. Hence, the MOSFET may be turned on anytime without being affected by negative voltage of the input voltage amplitude, thus improving the linearity of the switch. Since the switching circuit proposed by the present invention has better linearity, it is suitable to be applied upon audio products. For example, the switching circuit of the present invention may be coupled between a high-specification amplifier and a low power-consumption amplifier, thereby allowing the user to freely switch between different modes when using the audio product. For example, when the user is listening to music, the switching circuit of the present invention may be coupled to the high-specification amplifier for better user experience; and when the user is dialing, the switching circuit may be coupled to the low power-consumption amplifier to further reduce the overall power consumption, since fancy audiovisual effects are not necessary in this circumstance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuit, comprising:
a switch including a control terminal and an input terminal, the input terminal being arranged to receive an input voltage and the control terminal being arranged to receive a control voltage that controls a state of the switch; and
a level-shifting circuit including a level-shifting input terminal and a level-shifting output terminal, the level-shifting input terminal being coupled to the input terminal for receiving the input voltage, the level-shifting circuit being arranged to shift the input voltage for generating a shifted voltage at the level-shifting output terminal, and the control voltage being generated based on the shifted voltage.

2. The circuit of claim 1, wherein the switch comprises a Metal Oxide Semiconductor Field Effect Transistor (MOSFET).

3. The circuit of claim 2, wherein the control terminal is coupled to a gate of the MOSFET.

4. The circuit of claim 2, wherein the input terminal is coupled to a source of the MOSFET.

5. The circuit of claim 1, further comprising:
a buffering circuit, coupled between the level-shifting output terminal and the control terminal, the buffering circuit arranged to receive the shifted voltage at the level-shifting output terminal, for generating the control voltage at the control terminal.

6. The circuit of claim 1, wherein the buffering circuit comprises a first input terminal, a second input terminal and an output terminal, the second input terminal is coupled to the output terminal, the output terminal is coupled to the control terminal, and the first input terminal is coupled to the level-shifting output terminal of the level-shifting circuit.

7. The circuit of claim 1, wherein the level-shifting circuit comprises a first transistor, the level-shifting input terminal is coupled to a gate of the first transistor, and the level-shifting output terminal is coupled to a source of the first transistor.

8. The circuit of claim 7, wherein the level-shifting circuit further comprises a second transistor, the level-shifting output terminal is coupled to a drain of the second transistor, and a gate of the second transistor is coupled to a drain of the first transistor.

9. The circuit of claim 7, wherein the level-shifting circuit further comprises a current source coupled between a reference voltage and the source of the first transistor; or the level-shifting circuit further comprises a current source coupled between a reference voltage and a drain of the first transistor.

10. The circuit of claim 7, wherein the level-shifting circuit further comprises an amplifier, the level-shifting output terminal is coupled to an output terminal of the amplifier, and a first input terminal of the amplifier is coupled to a drain of the first transistor.
